(19) United States
(12) Patent Application Publication
(10) Pub. No.: US 2024/0315140 A1
(43) Pub. Date: Sep. 19, 2024

(54) Method for Manufacturing MRAM

(71) Applicant: ZHEJIANG HIKSTOR TECHNOLOGY CO., LTD., Hangzhou, Zhejiang (CN)

(72) Inventors: Ze Jie ZHENG, Hangzhou, Zhejiang (CN); Yue Jin WANG, Hangzhou, Zhejiang (CN); Shi Kun HE, Hangzhou, Zhejiang (CN)

(21) Appl. No.: 18/575,271

(22) PCT Filed: Dec. 2, 2022
(86) PCT No.: PCT/CN2022/136354

§ 371 Date: Dec. 28, 2023

(30) Foreign Application Priority Data
Mar. 30, 2022 (CN) 202210328369.X

(51) Int. Cl. H10N 50/01; G01R 33/09; H10B 61/00; H10N 50/10

(52) U.S. Cl. CPC H10N 50/01; H10B 61/10; G01R 33/098; H10N 50/10

(57) ABSTRACT

The disclosure provides a method for manufacturing a MRAM, wherein a prefabricated substrate structure is provided, on which at least one array zone bottom interconnection line, at least one bottom electrode and at least one magnetic tunnel junction, at least one logic zone bottom interconnection line, and a first medium layer are provided; a top electrode material layer and a hard mask material layer are formed on a surface of each of the at least one magnetic tunnel junction; the top electrode material layer and the hard mask material layer are photoetched and etched to form at least one top electrode and at least one hard mask layer; backfilling is conducted with a medium, and the backfilled medium is ground to be equal to the hard mask layer in height; the hard mask layer is selectively removed, and at least one array zone top via hole is formed through self-alignment.

### CROSS-REFERENCE TO RELATED APPLICATION

This disclosure claims the priority of Chinese Patent Application No. 202210328369.X filed in China on Mar. 30, 2022, the content of which is incorporated by reference herein in its entirety as part of this disclosure.

### TECHNICAL FIELD

The disclosure relates to the technical field of magnetoresistive random access memories (MRAMs), and particularly relates to a method for manufacturing an MRAM.

### BACKGROUND

A magnetoresistive random access memory (MRAM) features fast reading and writing, low power consumption, high density, high erase count, and capability to be integrated with a complementary metal oxide semiconductor (CMOS) technology, thereby being a novel promising memory. A magnetic tunnel junction (MTJ), a core unit of an MRAM chip, is also referred to as a bit. It is mainly composed of a magnetic free layer, an insulating layer, and a magnetic reference layer. A state of the magnetic free layer can be changed by a magnetic field or a spin-polarized current. A relative relation (a parallel state/an antiparallel state) between the magnetic free layer and the reference layer determines resistance of the bit, such that “0” or “1” information is stored.

The MRAM chip includes an array zone and a logic zone. An MTJ array is integrated into two layers of metal wiring of a CMOS back-end technology. For the array zone and the logic zone, conductive via holes in the array zone and the logic zone have different connection structures and requirements.

In an existing process flow, top conductive via holes, that is, an array zone top via hole and a logic zone via hole are formed by a photomask at the same time. The two via holes require different sizes and depth-width ratios, posing great challenge to the process.

### SUMMARY

The disclosure provides a method for manufacturing an MRAM. The method includes the following steps:
a prefabricated substrate structure is provided, where the substrate structure includes at least one array zone bottom interconnection line, at least one bottom electrode and at least one magnetic tunnel junction that are formed in an array zone, and further includes at least one logic zone bottom interconnection line that is formed in a logic zone, and a first medium layer;
a top electrode material layer and a hard mask material layer are formed on a surface of each of the at least one magnetic tunnel junction;
the top electrode material layer and the hard mask material layer are photoetched and etched to form at least one top electrode and at least one hard mask layer;
backfilling is conducted with a medium, and the backfilled medium is ground to be equal to each of the at least one hard mask layer in height by using each of the at least one hard mask layer as a grinding stop layer;
the at least one hard mask layer is selectively removed, and at least one array zone top via hole is formed through self-alignment; and
at least one logic zone via hole is provided independently.

In some embodiments, a thickness of each of the at least one hard mask material layer is set to be a thickness of the array zone top via hole formed later;

Accordingly, the method further includes the following steps:
the at least one array zone top via hole and the logic zone via hole are filled with metal;
an etching stop layer and a third medium layer are deposited;
an array zone top interconnection line pattern and a logic zone top interconnection line pattern are obtained through photoetching and etching; and
the array zone top interconnection line pattern and the logic zone top interconnection line pattern are filled with metal.

In some embodiments, a thickness of the hard mask material layer is set to be the sum of a thickness of each of the at least one array zone top via hole formed later and a thickness of each of the at least one array zone top interconnection line;

Accordingly, the method further includes the following steps:
an array zone top interconnection line pattern and a logic zone top interconnection line pattern are obtained in the backfilled medium through photoetching and etching; and
the at least one array zone top via hole, the array zone top interconnection line pattern, the at least one logic zone via hole and the logic zone top interconnection line pattern are filled with metal.

The disclosure provides a method for manufacturing an MRAM. The method includes the following steps:
a prefabricated substrate structure is provided, where the substrate structure includes at least one array zone bottom interconnection line, at least one bottom electrode and at least one magnetic tunnel junction that are formed in an array zone, and further includes at least one logic zone bottom interconnection line that is formed in a logic zone, and a first medium layer;
a top electrode material layer and a hard mask material layer are formed on a surface of each of the at least one magnetic tunnel junction;
the top electrode material layer and the hard mask material layer are photoetched and etched to form at least one top electrode and at least one hard mask layer;
backfilling is conducted with a medium, the backfilled medium is ground to be equal to the hard mask layer in height by using each of the at least one hard mask layer as a grinding stop layer;
the at least one hard mask layer is selectively removed, and an array zone top interconnection line pattern is formed through self-alignment; and
at least one logic zone via hole is provided independently.

In some embodiments, the method further includes the following steps:
a logic zone top interconnection line pattern is obtained in the backfilled medium through photoetching and etching; and
the array zone top interconnection line pattern, the logic zone via hole and the logic zone top interconnection line pattern are filled with metal.

In some embodiments, the step that the top electrode material layer and the hard mask material layer are formed on the surface of the magnetic tunnel junction includes the following steps:
a covering layer and a second medium layer are deposited;
planarization is conducted to expose the surface of the at least one magnetic tunnel junction; and
the top electrode material layer and the hard mask material layer are deposited.

In some embodiments, when the top electrode material layer is etched, etching stops at the second medium layer on the covering layer or the first medium layer under the covering layer.

In some embodiments, a grinding selection ratio of the at least one hard mask layer to the backfilled medium is greater than 10:1.

In some embodiments, an etching selection ratio of the at least one hard mask layer to the backfilled medium is greater than 10:1.

In some embodiments, the at least one hard mask layer is made of oxide or nitride.

### BRIEF DESCRIPTION OF THE DRAWINGS

FIGS. 1A-1H show a schematic diagram of a process flow of a method for manufacturing a magnetoresistive random access memory (MRAM) according to an embodiment of the disclosure;

FIGS. 2A-2H show a schematic diagram of a process flow of a method for manufacturing an MRAM according to an embodiment of the disclosure;

FIGS. 3A-3H show a schematic diagram of a process flow of a method for manufacturing an MRAM according to an embodiment of the disclosure;

FIGS. 4A-4H show a schematic diagram of a process flow of a method for manufacturing an MRAM according to an embodiment of the disclosure.

### DETAILED DESCRIPTION OF THE EMBODIMENTS

For making objectives, technical solutions and advantages of embodiments of the disclosure clearer, the technical solutions of the embodiments of the disclosure will be clearly and completely described below in conjunction with the accompanying drawings in the embodiments of the disclosure. However, it should be understood that the description is only illustrative and is not intended to limit the scope of the disclosure. All other embodiments obtained by those of ordinary skill in the art based on the embodiments of the disclosure without creative efforts shall fall within the protection scope of the disclosure. Further, description of well-known structures and technologies is omitted in the following description, such that concepts of the disclosure are prevented from being unnecessarily confused.

Various schematic structural diagrams according to the embodiments of the disclosure are shown in the drawings. The drawings are not drawn to scale, in which some details are exaggerated and some details may be omitted for the purpose of clear expression. Shapes of various zones and layers shown in the figures and their relative sizes and positional relations are only illustrative, and may actually be deviated due to manufacturing tolerances or technical limitations. Those skilled in the art may additionally design zones/layers having different shapes, sizes and relative positions according to actual needs.

In context of the disclosure, when a layer/element is described to be located “on” another layer/element, the layer/element may be directly located on another layer/element. In some embodiments, an intervening layer/element may exist between the layers/elements. In addition, if a layer/element is located “on” another layer/element in a direction, the layer/element may be located “under” another layer/element when the direction is reversed.

Some embodiments of the disclosure will be described in detail with reference to the accompanying drawings. The following embodiments and features in the embodiments may be combined with each other without conflict.

The improved solution of the disclosure mainly lies in a top interconnection structure of an array zone and a logic zone of a magnetoresistive random access memory (MRAM). The top interconnection structure may be divided into two cases that the top interconnection structure has a top via hole (TV) or the top interconnection structure has no top via hole (TV), which will be discussed below according to the cases separately.

1. In the Case where the Top Interconnection Structure has a Top Via Hole (TV)

### Embodiment 1

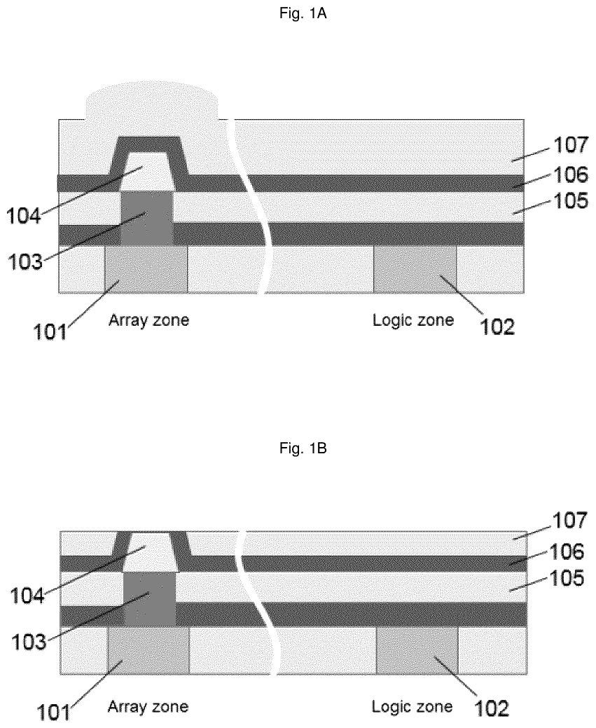

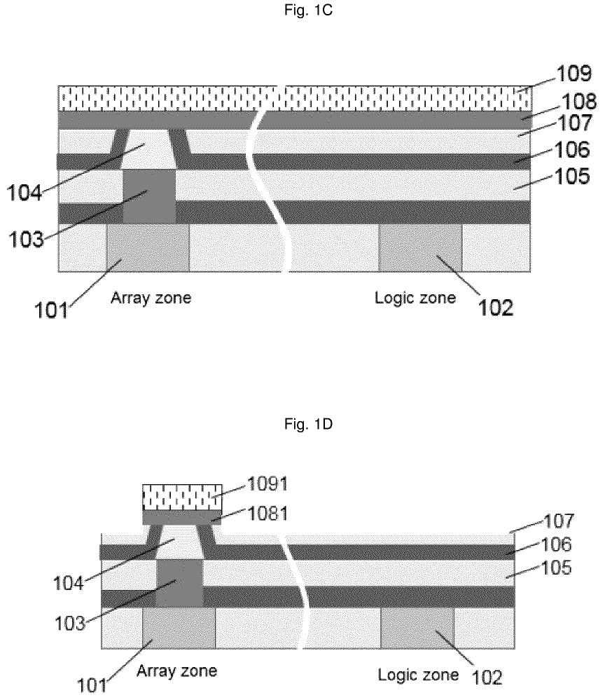

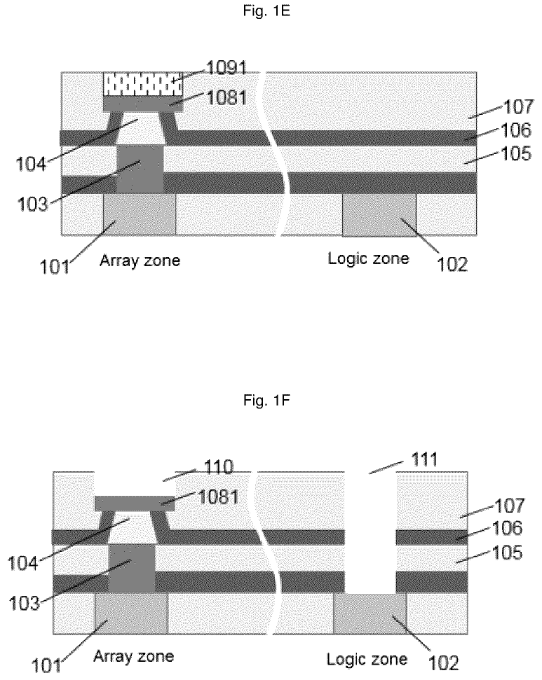

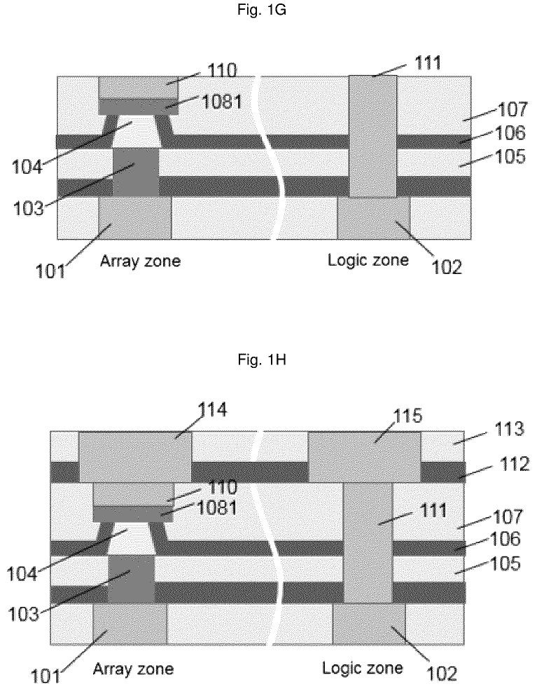

The embodiment of the disclosure provides a method for manufacturing an MRAM. FIGS. 1A-1H show section views of structures corresponding to all steps of the entire manufacturing method.

With reference to FIG. 1A, firstly, a prefabricated substrate structure is provided. The substrate structure includes an array zone bottom interconnection line 101, a bottom electrode 103 and a magnetic tunnel junction 104 that are formed in an array zone, and further includes a logic zone bottom interconnection line 102 that is formed in a logic zone, and a first medium layer 105. A covering layer 106 and a second medium layer 107 are deposited on the substrate structure.

With reference to FIG. 1B, planarization is conducted to expose a surface of the magnetic tunnel junction 104.

With reference to FIG. 1C, a top electrode material layer 108 and a hard mask material layer 109 are deposited. In the embodiment, a thickness of the hard mask material layer 109 is set to be a first thickness. The first thickness is a thickness of an array zone top via hole (TV) formed later.

With reference to FIG. 1D, the top electrode material layer 108 and the hard mask material layer 109 are photoetched and etched to form a top electrode 1081 and a hard mask layer 1091. It should be noted that in the step, etching may stop at the second medium layer 107 on the covering layer 106 or stop at the first medium layer 105 under the covering layer 106, which is not particularly limited herein. FIG. 1D shows a case where etching stops at the second medium layer 107.

With reference to FIG. 1E, backfilling is conducted with a medium, then the backfilled medium is ground to be equal to the hard mask layer 1091 in height by using the hard mask layer 1091 as a grinding stop layer. The backfilled medium and the second medium layer 107 may be made of the same material. The hard mask layer 1091 and the backfilled medium have a great grinding selection ratio, which is greater than 10:1.

With reference to FIG. 1F, the hard mask layer 1091 is selectively removed to expose the top electrode 1081. In this way, the array zone top via hole 110 may be formed through self-alignment at a vacant position where the hard mask layer 1091 is removed. Then, a logic zone via hole 111 is provided independently. The hard mask layer 1091 is removed through dry etching or wet etching. The hard mask layer 1091 and the backfilled medium have a great etching selection ratio, which is greater than 10:1. For instance, the hard mask layer may be an oxide or nitride medium, and the hard mask layer and the backfilled medium need to satisfy the above requirements. That is, the grinding selection ratio is greater than 10:1, and the etching selection ratio is greater than 10:1. In some embodiments, the hard mask layer may be a metal layer.

Further, after the array zone top via hole 110 and the logic zone via hole 111 are obtained, a top interconnection line is manufactured. The step is specifically as follows:

With reference to FIG. 1G, the array zone top via hole 110 and the logic zone via hole 111 are filled with metal.

With reference to FIG. 1H, an etching stop layer 112 and a third medium layer 113 are deposited, an array zone top interconnection line pattern 114 and a logic zone top interconnection line pattern 115 are obtained through photoetching and etching, and the array zone top interconnection line pattern 114 and the logic zone top interconnection line pattern 115 are filled with metal. In the method, top via hole filling and top interconnection line filling are conducted separately.

### Embodiment 2

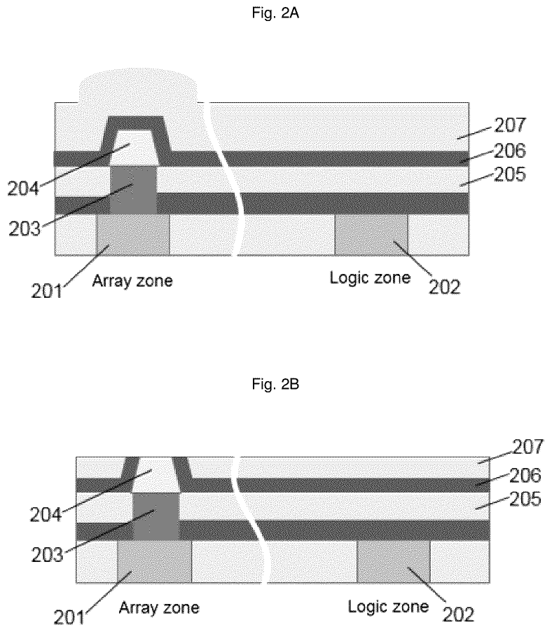

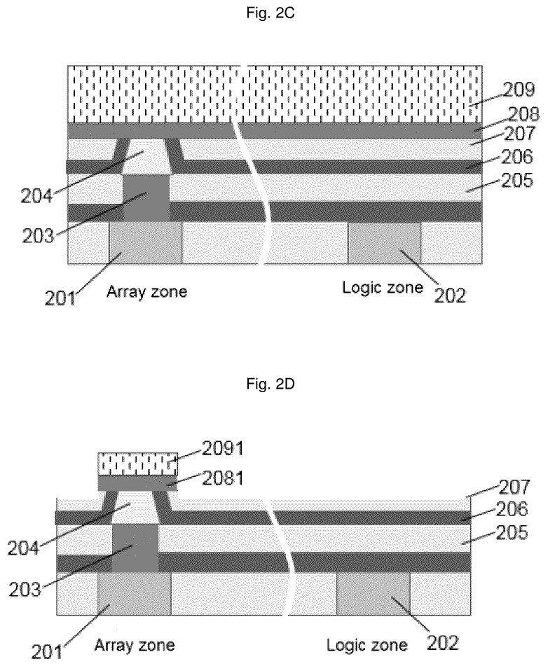

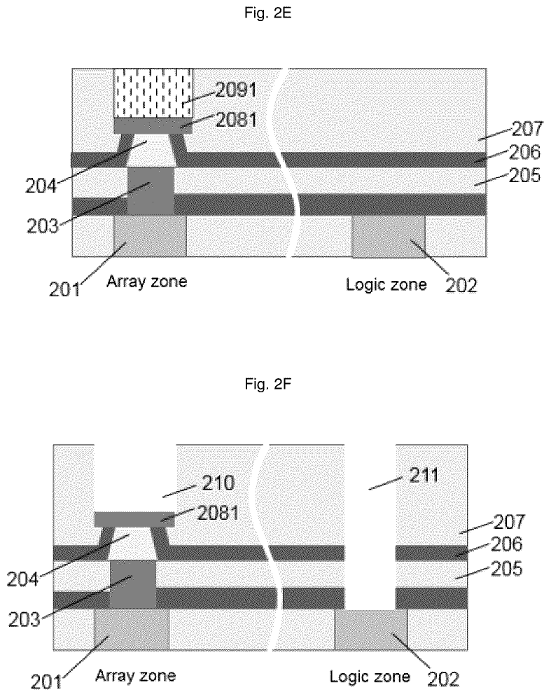

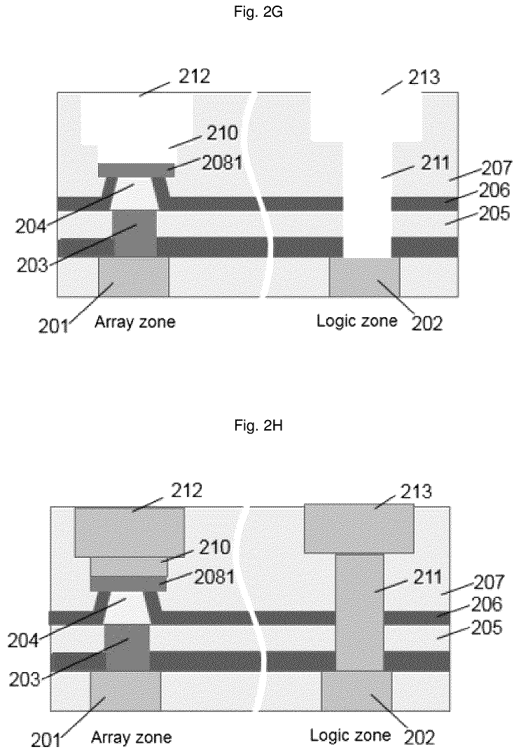

As another embodiment, top via hole filling and top interconnection line filling are conducted at a time. In the embodiment, a process of forming an array zone top via hole and a logic zone via hole is similar to that of the last embodiment, and reference is made to a manufacturing process in FIGS. 2A-2H for details.

With reference to FIG. 2A, firstly, a prefabricated substrate structure is provided. The substrate structure includes an array zone bottom interconnection line 201, a bottom electrode 203 and a magnetic tunnel junction 204 that are formed in an array zone, and further includes a logic zone bottom interconnection line 202 that is formed in a logic zone, and a first medium layer 205. A covering layer 206 and a second medium layer 207 are deposited on the substrate structure.

With reference to FIG. 2B, planarization is conducted to expose a surface of the magnetic tunnel junction 204.

With reference to FIG. 2C, a top electrode material layer 208 and a hard mask material layer 209 are deposited. In the embodiment, a thickness of the hard mask material layer 209 is set to be a second thickness. The second thickness is the sum of a thickness of the array zone top via hole formed later and a thickness of an array zone top interconnection line.

With reference to FIG. 2D, the top electrode material layer 208 and the hard mask material layer 209 are photoetched and etched to form a top electrode 2081 and a hard mask layer 2091. It should be noted that in the step, etching may stop at the second medium layer 207 on the covering layer 206 or stop at the first medium layer 205 under the covering layer 206, which is not particularly limited herein. FIG. 2D shows a case where etching stops at the second medium layer 207.

With reference to FIG. 2E, backfilling is conducted with a medium, then the backfilled medium is ground to be equal to the hard mask layer 2091 in height by using the hard mask layer 2091 as a grinding stop layer. The backfilled medium and the second medium layer 207 may be made of the same material.

With reference to FIG. 2F, the hard mask layer 2091 is selectively removed to expose the top electrode 2081. In this way, the array zone top via hole 210 may be formed through self-alignment at a vacant position where the hard mask layer 2091 is removed. Then, a logic zone via hole 211 is provided independently.

As mentioned above, in the embodiment, the thickness of the hard mask material layer is increased, which is the sum of the thickness of the array zone top via hole formed and the thickness of the array zone top interconnection line. Therefore, the subsequent steps of preparing the top interconnection line specifically include:

With reference to FIG. 2G, an array zone top interconnection line pattern 212 and a logic zone top interconnection line pattern 213 are obtained in the backfilled medium through photoetching and etching.

With reference to FIG. 2H, the array zone top via hole 210, the array zone top interconnection line pattern 212, the logic zone via hole 211 and the logic zone top interconnection line pattern 213 are filled with metal.

The method for manufacturing an MRAM according to the embodiment is suitable for the case where the top interconnection structure has a top via hole (TV). A process flow is improved. The hard mask layer is arranged on an array zone top electrode. The hard mask layer and a medium layer backfilled after etching have a great grinding selection ratio. A hard mask is used as a planarization stop layer. In-plane uniformity of a wafer edge is better, a process window is larger, and controllability is stronger. The array zone top via hole is formed through self-alignment, and the top interconnection line is connected to the top electrode by means of the top via hole, such that only the logic zone via hole needs to be provided independently, and a process is simple and controllable.

2. In the Case where the Top Interconnection Structure has No Top Via Hole (TV)

### Embodiment 3

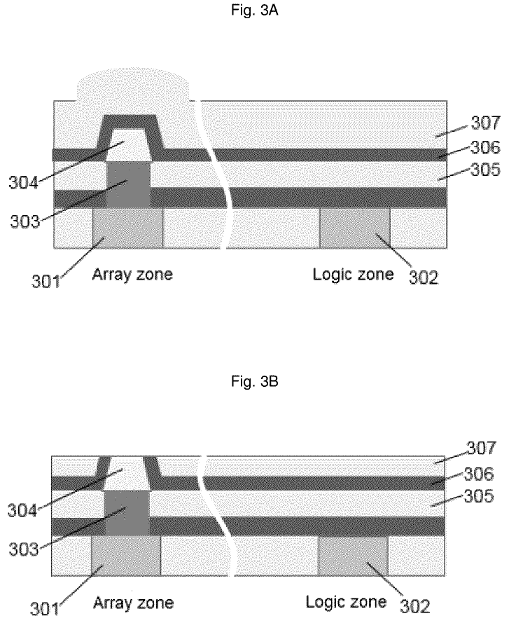

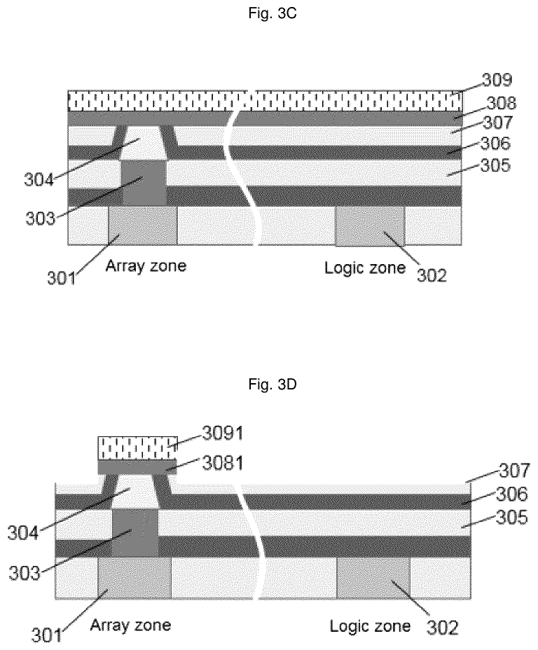

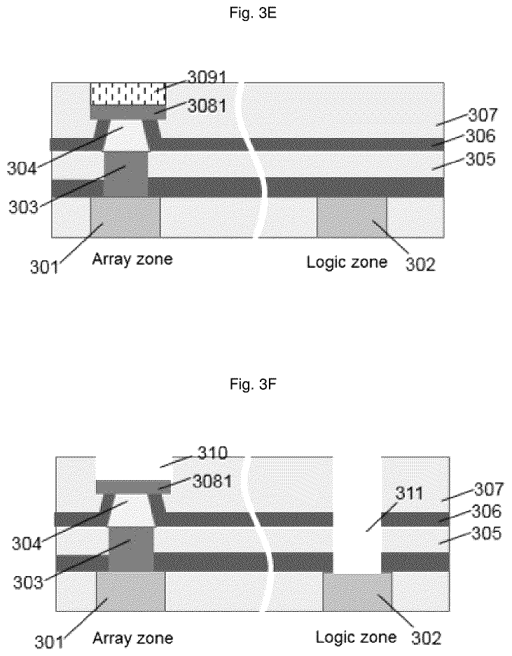

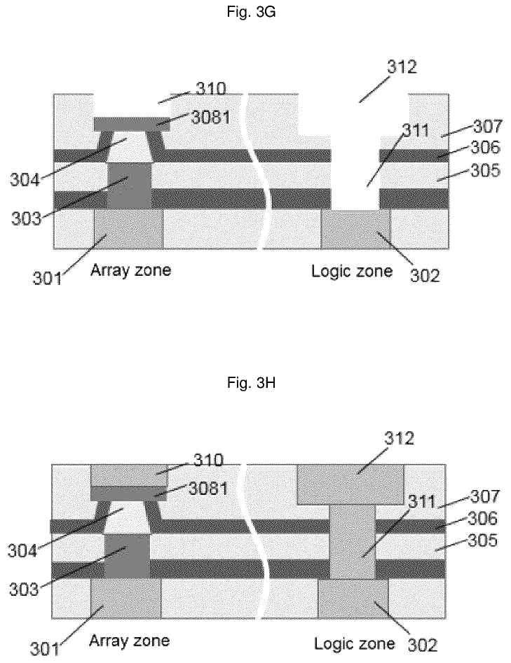

The embodiment of the disclosure provides a method for manufacturing an MRAM. FIGS. 3A-3H show section views of structures corresponding to all steps of the entire manufacturing method.

With reference to FIG. 3A, firstly, a prefabricated substrate structure is provided. The substrate structure includes an array zone bottom interconnection line 301, a bottom electrode 303 and a magnetic tunnel junction 304 that are formed in an array zone, and further includes a logic zone bottom interconnection line 302 that is formed in a logic zone, and a first medium layer 305. A covering layer 306 and a second medium layer 307 are deposited on the substrate structure.

With reference to FIG. 3B, planarization is conducted to expose a surface of the magnetic tunnel junction 304.

With reference to FIG. 3C, a top electrode material layer 308 and a hard mask material layer 309 are deposited. In the embodiment, a top via hole does not need to be formed finally. A thickness of the hard mask material layer 309 is set to be a third thickness. The third thickness is a thickness of an array zone top interconnection line formed later.

With reference to FIG. 3D, the top electrode material layer 308 and the hard mask material layer 309 are photoetched and etched to form a top electrode 3081 and a hard mask layer 3091. It should be noted that in the step, etching may stop at the second medium layer 307 on the covering layer 306 or stop at the first medium layer 305 under the covering layer 306, which is not particularly limited herein. FIG. 3D shows a case where etching stops at the second medium layer 307.

With reference to FIG. 3E, backfilling is conducted with a medium, then the backfilled medium is ground to be equal to the hard mask layer 3091 in height by using the hard mask layer 3091 as a grinding stop layer. The backfilled medium and the second medium layer 307 may be made of the same material.

With reference to FIG. 3F, the hard mask layer 3091 is selectively removed to expose the top electrode 3081. In this way, an array zone top interconnection line pattern 310 may be formed through self-alignment at a vacant position where the hard mask layer 3091 is removed. Then, a logic zone via hole 311 is provided independently.

Further, after the array zone top interconnection line pattern 310 and the logic zone via hole 311 are obtained, a top interconnection line is manufactured. The step is specifically as follows:

With reference to FIG. 3G, a logic zone top interconnection line pattern 312 is obtained in the backfilled medium through photoetching and etching. With reference to FIG. 3H, the array zone top interconnection line pattern 310, the logic zone via hole 311 and the logic zone top interconnection line pattern 312 are filled with metal.

### Embodiment 4

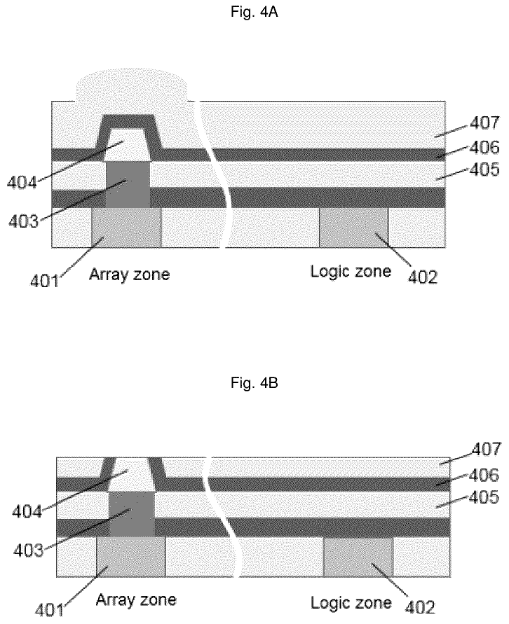

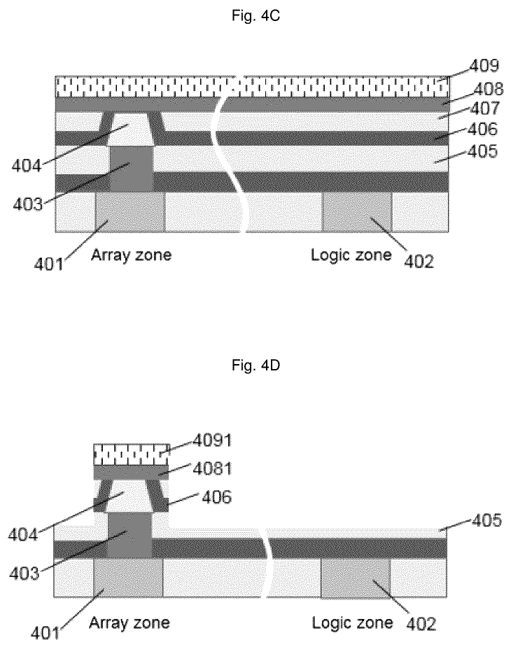

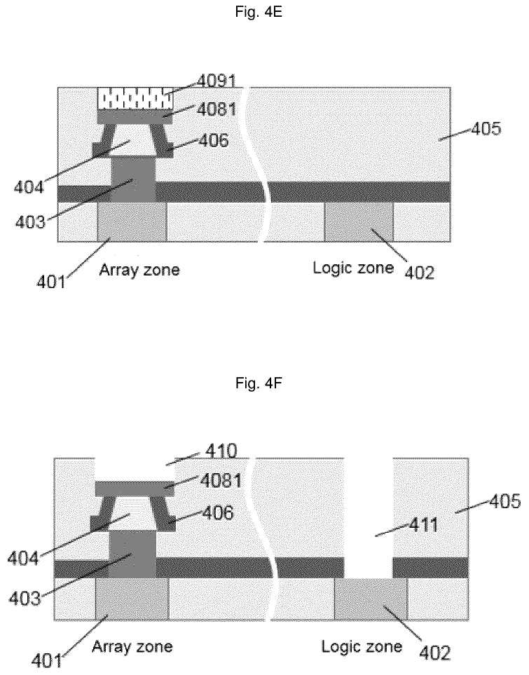

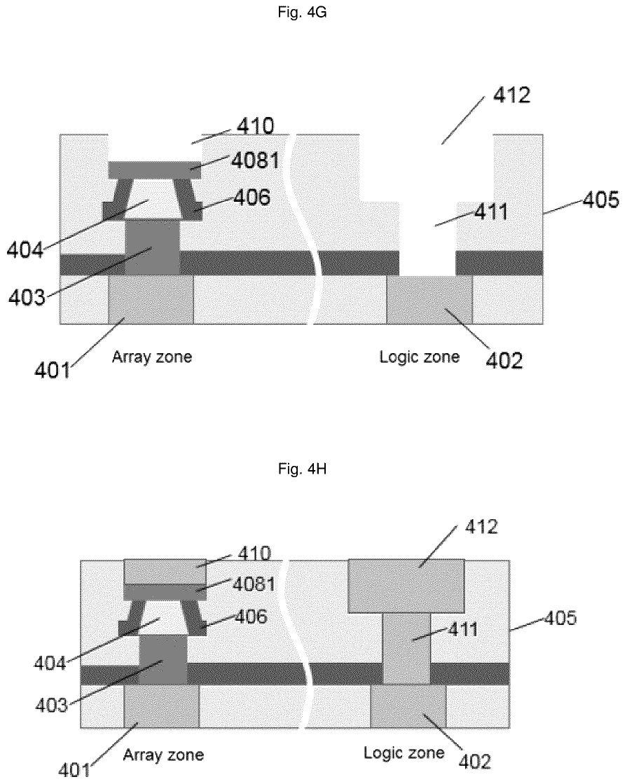

As another embodiment, FIGS. 4A-4H show section views of structures corresponding to all steps of the entire manufacturing method of Embodiment 4.

With reference to FIG. 4A, firstly, a prefabricated substrate structure is provided. The substrate structure includes an array zone bottom interconnection line 401, a bottom electrode 403 and a magnetic tunnel junction 404 that are formed in an array zone, and further includes a logic zone bottom interconnection line 402 that is formed in a logic zone, and a first medium layer 405. A covering layer 406 and a second medium layer 407 are deposited on the substrate structure.

With reference to FIG. 4B, planarization is conducted to expose a surface of the magnetic tunnel junction 404.

With reference to FIG. 4C, a top electrode material layer 408 and a hard mask material layer 409 are deposited. In the embodiment, a top via hole does not need to be formed finally. A thickness of the hard mask material layer 409 is set to be a thickness of an array zone top interconnection line formed.

With reference to FIG. 4D, the top electrode material layer 408 and the hard mask material layer 409 are photoetched and etched to form a top electrode 4081 and a hard mask layer 4091. In the embodiment, etching stops at a first medium layer 405.

With reference to FIG. 4E, backfilling is conducted with a medium, then the backfilled medium is ground to be equal to the hard mask layer 4091 in height by using the hard mask layer 4091 as a grinding stop layer. The backfilled medium and the first medium layer 405 may be made of the same material.

With reference to FIG. 4F, the hard mask layer 4091 is selectively removed to expose the top electrode 4081. In this way, an array zone top interconnection line pattern 410 may be formed through self-alignment at a vacant position where the hard mask layer 4091 is removed. Then, a logic zone via hole 411 is provided independently.

Further, after the array zone top interconnection line pattern 410 and the logic zone via hole 411 are obtained, a top interconnection line is manufactured. The step is specifically as follows:

With reference to FIG. 4G, a logic zone top interconnection line pattern 412 is obtained in the backfilled medium through photoetching and etching. With reference to FIG. 4H, the array zone top interconnection line pattern 410, the logic zone via hole 411 and the logic zone top interconnection line pattern 412 are filled with metal.

Compared with Embodiment 3, Embodiment 4 is different in that when the top electrode material layer 408 and the hard mask material layer 409 are etched, an etching end point is placed on the first medium layer under a covering layer. Similarly, Embodiment 1 and Embodiment 2 may also place the etching end point on the first medium layer under the covering layer, which will not be described in details herein.

In addition, in the above embodiments, the hard mask layer is selectively removed, the array zone top via hole or the array zone top interconnection line pattern is obtained, and then the logic zone via hole is provided. It may be understood that the hard mask layer may be removed to expose an array zone top electrode after the logic zone via hole and the logic zone top interconnection line pattern are formed, and finally filling is conducted with metal.

The method for manufacturing an MRAM according to the embodiment of the disclosure is suitable for the case where the top interconnection structure has no top via hole (TV). A process flow is improved. The hard mask layer is arranged on an array zone top electrode. The hard mask layer and a medium layer backfilled after etching have a great grinding selection ratio. A hard mask is used as a planarization stop layer. In-plane uniformity of a wafer edge is better, a process window is larger, and controllability is stronger. The array zone top interconnection line is formed through self-alignment, and the top interconnection line is directly connected to the top electrode, such that only the logic zone via hole needs to be provided independently, and a process is simple and controllable.

In the above description, the technical details such as patterning and etching of each layer are not described in details. However, those skilled in the art should understand that layers, zones, etc. having desired shapes may be formed by various technical means. In addition, in order to form the same structure, those skilled in the art may also design methods that are not exactly the same as those described above. In addition, although each embodiment has been described separately above, it is not indicated that the measures in each embodiment cannot be used in combination.

What are described above are merely specific embodiments of the disclosure, which are not intended to limit the protection scope of the disclosure. Any changes or substitutions that may be easily conceived by those skilled in the art within the technical scope disclosed in the disclosure are intended to fall within the protection scope of the disclosure. Therefore, the protection scope of the disclosure should be subject to the protection scope of the claims.

1. A method for manufacturing a magnetoresistive random access memory (MRAM), comprising:
providing a prefabricated substrate structure, wherein the substrate structure comprises at least one array zone bottom interconnection line, at least one bottom electrode and at least one magnetic tunnel junction that are formed in an array zone, and further comprises at least one logic zone bottom interconnection line that is formed in a logic zone, and a first medium layer;
forming a top electrode material layer and a hard mask material layer on a surface of each of the at least one magnetic tunnel junction;
photoetching and etching the top electrode material layer and the hard mask material layer to form at least one top electrode and at least one hard mask layer;
conducting backfilling with a medium, grinding the backfilled medium to be equal to each of the at least one hard mask layer in height by using each of the at least one hard mask layer as a grinding stop layer;
selectively removing the at least one hard mask layer, and forming at least one array zone top via hole through self-alignment; and
providing at least one logic zone via hole independently.

2. The method according to claim 1, wherein
a thickness of the hard mask material layer is set to be a thickness of each of the at least one array zone top via hole formed later; and
accordingly, the method further comprises:
filling the at least one array zone top via hole and the logic zone via hole with metal;
depositing an etching stop layer and a third medium layer;
obtaining an array zone top interconnection line pattern and a logic zone top interconnection line pattern through photoetching and etching; and
filling the array zone top interconnection line pattern and the logic zone top interconnection line pattern with metal.

3. The method according to claim 1, wherein
a thickness of the hard mask material layer is set to be the sum of a thickness of each of the at least one array zone top via hole formed later and a thickness of each of the at least one array zone top interconnection line; and
accordingly, the method further comprises:
obtaining an array zone top interconnection line pattern and a logic zone top interconnection line pattern in the backfilled medium through photoetching and etching; and
filling the at least one array zone top via hole, the array zone top interconnection line pattern, the at least one logic zone via hole and the logic zone top interconnection line pattern with metal.

4. A method for manufacturing an MRAM, comprising:
providing a prefabricated substrate structure, wherein the substrate structure comprises at least one array zone bottom interconnection line, at least one bottom electrode and at least one magnetic tunnel junction that are formed in an array zone, and further comprises at least one logic zone bottom interconnection line that is formed in a logic zone, and a first medium layer;
forming a top electrode material layer and a hard mask material layer on a surface of each of the at least one magnetic tunnel junction;
photoetching and etching the top electrode material layer and the hard mask material layer to form at least one top electrode and at least one hard mask layer;
conducting backfilling with a medium, grinding the backfilled medium to be equal to each of the at least one hard mask layer in height by using each of the at least one hard mask layer as a grinding stop layer;
selectively removing the at least one hard mask layer, and forming an array zone top interconnection line pattern through self-alignment; and
providing at least one logic zone via hole independently.

5. The method according to claim 4, further comprising:
obtaining a logic zone top interconnection line pattern in the backfilled medium through photoetching and etching; and
filling the array zone top interconnection line pattern, the logic zone via hole and the logic zone top interconnection line pattern with metal.

6. The method according to claim 1, wherein the forming a top electrode material layer and a hard mask material layer on a surface of the magnetic tunnel junction comprises:
depositing a covering layer and a second medium layer;
conducting planarization to expose the surface of the at least one magnetic tunnel junction; and
depositing the top electrode material layer and the hard mask material layer.

7. The method according to claim 6, wherein when the top electrode material layer is etched, etching stops at the second medium layer on the covering layer or the first medium layer under the covering layer.

8. The method according to claim 1, wherein a grinding selection ratio of the at least one hard mask layer to the backfilled medium is greater than 10:1.

9. The method according to claim 1, wherein an etching selection ratio of the at least one hard mask layer to the backfilled medium is greater than 10:1.

10. The method according to claim 1, wherein the at least one hard mask layer is made of oxide or nitride.

11. The method according to claim 2, wherein the forming a top electrode material layer and a hard mask material layer on a surface of the magnetic tunnel junction comprises:
depositing a covering layer and a second medium layer;
conducting planarization to expose the surface of the at least one magnetic tunnel junction; and
depositing the top electrode material layer and the hard mask material layer.

12. The method according to claim 3, wherein the forming a top electrode material layer and a hard mask material layer on a surface of the magnetic tunnel junction comprises:
depositing a covering layer and a second medium layer;
conducting planarization to expose the surface of the at least one magnetic tunnel junction; and
depositing the top electrode material layer and the hard mask material layer.

13. The method according to claim 4, wherein the forming a top electrode material layer and a hard mask material layer on a surface of the magnetic tunnel junction comprises:
depositing a covering layer and a second medium layer;
conducting planarization to expose the surface of the at least one magnetic tunnel junction; and
depositing the top electrode material layer and the hard mask material layer.

14. The method according to claim 5, wherein the forming a top electrode material layer and a hard mask material layer on a surface of the magnetic tunnel junction comprises:
depositing a covering layer and a second medium layer;
conducting planarization to expose the surface of the at least one magnetic tunnel junction; and
depositing the top electrode material layer and the hard mask material layer.

15. The method according to claim 2, wherein a grinding selection ratio of the at least one hard mask layer to the backfilled medium is greater than 10:1.

16. The method according to claim 3, wherein a grinding selection ratio of the at least one hard mask layer to the backfilled medium is greater than 10:1.

17. The method according to claim 4, wherein a grinding selection ratio of the at least one hard mask layer to the backfilled medium is greater than 10:1.

18. The method according to claim 5, wherein a grinding selection ratio of the at least one hard mask layer to the backfilled medium is greater than 10:1.

19. The method according to claim 2, wherein an etching selection ratio of the at least one hard mask layer to the backfilled medium is greater than 10:1.

20. The method according to claim 3, wherein an etching selection ratio of the at least one hard mask layer to the backfilled medium is greater than 10:1.
